(19) United States
(12) Patent Application Publication
(10) Pub. No.: US 2015/0325766 A1
(43) Pub. Date: Nov. 12, 2015

(54) THEMOELECTRIC DEVICE

(71) Applicant: Mahle Behr GmbH & Co. KG, Stuttgart (DE)

(72) Inventors: Thomas Himmer, Reichenbach (DE); Holger Schroth, Maulbronn (DE)

(21) Appl. No.: 14/704,248

(22) Filed: May 5, 2015

(30) Foreign Application Priority Data
May 6, 2014 (DE) 102014208433.4

(51) Int. Cl. H01L 35/32

(52) U.S. Cl. CPC H01L 35/32

(57) ABSTRACT

A thermoelectric device such as that for a motor vehicle may include a housing having a first housing part and a second housing part at least partially delimiting a housing interior. The first housing part and the second housing part may each include a housing wall, which are arranged opposite one another. At least one housing wall may have at least two receiving regions. The at least two receiving regions may respectively include at least one thermoelectric element arranged thereon. The at least two receiving regions may each be surrounding by a surround extending along a circulation direction. The surround of the at least two receiving regions may include a spring-elastic structure.

### CROSS REFERENCE TO RELATED APPLICATIONS

This application claims priority to German Patent Application No. DE 102014208433.4, filed May 6, 2014, the contents of which is hereby incorporated by reference in its entirety.

### TECHNICAL FIELD

The invention relates to a thermoelectric device, in particular for a motor vehicle and a motor vehicle with at least one such thermoelectric device.

### BACKGROUND

The term “thermoelectricity” is understood to mean the reciprocal influencing of temperature and electricity and their conversion into one another. Thermoelectric materials utilize this influence in order to generate electrical energy as thermoelectric generators from waste heat, but are also used in the form of so-called heat pumps if, with the expenditure of electrical energy, heat is to be transported from a temperature reservoir with lower temperature into one with higher temperature.

The said thermoelectric generators are in fact used in automotive engineering in the cooling of the most varied of components such as e.g. modern lithium-ion batteries, which develop waste heat to a considerable extent under normal operating conditions. Such thermoelectric generators can, however, also be used in electric motor vehicles as a combined heating and cooling device, for instance for controlling the temperature of the passenger compartment, especially since they have a distinctly higher efficiency than for instance conventional electric resistance heaters; in motor vehicles with an internal combustion engine, the waste heat generated in the exhaust gas during the combustion process can be partially converted into electrical energy and fed into the on-board electrical system of the motor vehicle. The waste heat, converted into electrical energy, can therefore be utilized to a considerable proportion in order to reduce the energy consumption of the motor vehicle to a necessary minimum and hence to prevent an unnecessary emission of exhaust gases, such as CO₂ for instance. The fields of application of thermoelectric devices in vehicle manufacturing are therefore multifaceted; in each of the said fields of application, it is of crucial importance to achieve as high an efficiency as possible, in order to be able to convert heat into electrical energy or vice versa as effectively as possible.

However, in thermoelectric devices known from the prior art, the thermomechanical stresses regularly occurring at the housing of such a device, caused by local temperature fluctuations, prove to be a problem. These can, in turn, be transmitted to the thermoelectric elements received in the interior of the housing, which can result in their damage or destruction.

Thermomechanical stresses occur especially when the different materials of the various components of the thermoelectric device, such as for instance housing, electrical insulation, conductor bridge, etc. with different coefficients of thermal expansion are connected with one another in a materially bonded manner and these are then exposed to different temperatures during operation. In addition, further thermomechanical stresses occur through the simultaneous presence both of a cold side and of a hot side on the module.

### SUMMARY

It is therefore an object of the present invention to provide a thermoelectric device with an improved housing, in which the said problem no longer occurs or only occurs in a moderated form.

This problem is solved by the subject of the independent claims. Preferred embodiments are the subject of the dependent claims.

Accordingly, the basic idea of the invention is to provide a spring-elastic structure in the housing walls of the thermoelectric device, which is able to receive any thermomechanical stresses occurring in the housing walls, or, alternatively thereto, to construct the respective housing wall to be sufficiently thin-walled, so that the material of the housing wall itself has the spring-elastic characteristics necessary for receiving the said thermoelectric stresses.

In the former case, the spring-elastic structure forms a surround for at least two receiving regions provided in the housing wall, in which respectively a thermoelectric element can be arranged. As the thermomechanical stresses are received according to the invention by the spring-elastic structure and in so doing lead to a local elastic deformation of the structure, the regions actually critical for deformations, namely said receiving regions at which the thermoelectric elements are fastened to the housing walls, remain free of such mechanical stresses. An undesired damage or even destruction of the structural integrity of the thermoelectrically active elements which are sensitive with respect to mechanical stresses can be avoided in this way. This also applies to the above-mentioned case of a sufficiently thin-walled construction of the housing wall of the housing providing the receiving regions.

In a first aspect, a thermoelectric device according to the invention comprises a housing comprising a first and a second housing part and at least partially delimiting a housing interior, wherein the two housing parts respectively comprise a housing wall which lie opposite one another in a mounted state. At least one of the two housing walls has at least two receiving regions, on which respectively a thermoelectric element is arranged. Adjacent thermoelectric elements can be connected with one another electrically and mechanically here by means of so-called metallic conductor paths—designated hereinbelow as “conductor path elements”—known to the relevant specialist in the art.

Each receiving region is enclosed here by a surround running along a circulation direction, which surround has a spring-elastic structure. The circumferential construction of the spring-elastic structure around a respective receiving region makes provision, as previously discussed, that the receiving region of the housing wall, surrounded by the surround, remains largely or even completely free of undesired thermomechanical stresses.

In an advantageous embodiment, the receiving region has substantially the geometry of a rectangle, in particular with rounded corners, with respect to a top view onto the housing wall. This means that the geometry of the receiving region is adapted to that of the thermoelectric elements, which typically have the geometrical shape of a cuboid.

In an advantageous further development, the spring-elastic structure producing the surround is constructed in a grid-like manner with respect to a top view onto the housing wall and comprises at least two grid lines and at least two grid gaps. The arrangement of the grid lines and grid gaps takes place here such that they cross each other in at least one crossing point. Preferably, the grid lines and grid gaps are arranged at a right angle to one another, so that the receiving regions are produced with a rectangular shape.

In a further preferred embodiment, a wall thickness of the housing wall is reduced in the region of the spring-elastic structure with respect to the region of the housing wall complementary to the spring-elastic structure. In this way, the spring-elastic structure is given in a particularly distinct form the spring-elastic characteristics necessary for receiving thermomechanical stresses.

However, an embodiment proves to be advantageous from the point of view of manufacturing technology, in which the spring-elastic structure comprises at least one bead formed integrally on the housing wall. This projects inwards from the housing wall into the housing space. Such a bead can be produced for instance by means of a so-called beading machine known to the relevant specialist in the art.

In another advantageous embodiment, alternative to the preceding embodiment, the spring-elastic structure has at least two, preferably a plurality of apertures running along the circulation direction of the surround, which are interrupted by at least one web formed integrally on the housing wall.

Particularly expediently, a web can connect two adjacent receiving regions, by bridging an aperture transversely to the circulation direction.

An embodiment in which the web has a substantially S-like geometry with respect to a top view onto the housing base has particularly good spring-elastic characteristics.

This applies to a particular extent to an advantageous further development, in which each surround, surrounding a particular receiving region, is provided with precisely six webs.

An embodiment is particularly simple to produce from the point of view of manufacturing technology, in which at least one, preferably each, surround surrounding a particular receiving region has two longitudinal sides and two transverse sides, wherein in each longitudinal side precisely two webs are provided, and in each transverse side precisely one web is provided.

In an advantageous further development, at least one web, preferably all webs, can have a geometric shape which is curved inwards, away from the housing base, towards the interior of the housing.

In an advantageous further development, the at least one web can taper in cross-section away from the housing wall towards the interior of the housing. This permits a particularly simple production of such a web, for instance in the course of a combined stamping forming process for stamping out said apertures.

A particularly good receiving of thermomechanical stresses, in particular when these occur locally at sites in the housing wall spaced apart from one another, can be achieved when at least two apertures and at least two webs alternate along the circulation direction. Preferably this may apply to a plurality of apertures or respectively webs. The grid lines and two grid gaps described above can be formed here by apertures and webs. In other words, webs and apertures alternate both along the circulation direction, which runs along the surround surrounding the receiving region, and also along said grid lines or respectively grid gaps.

In another advantageous embodiment, the webs and/or the apertures can be arranged in a wall plane defined by the housing wall, i.e. in such a scenario, a substantially flat, i.e. two-dimensional wall structure is produced. Alternatively thereto, the webs can, however, also project at least partially from the wall plane inwards into the interior of the housing. This facilitates the production of the webs in the course of a stamping process for the introduction of the already mentioned apertures into the housing wall.

In an advantageous further development, which is produced using a stamping process, an edge section of the housing wall, running along the circulation direction and partially delimiting the apertures, projects inwards into the interior of the housing.

Particularly distinct spring-elastic characteristics can be given to the structure essential to the invention, by the bead being equipped with a U-shaped or Ω-shaped profile in the cross-section of the housing wall.

As already explained, both the apertures and also the webs can be produced in the course of a shared stamping process which is particularly advantageous from the point of view of manufacturing technology.

In a further preferred embodiment, on a side of the first housing part facing away from the interior of the housing a film of an electrically conductive material, in particular of a metal, or else of an electrically non-conductive material is applied, which covers the apertures. In this way, the housing interior of the housing can be sealed with respect to the external environment of the housing, without this involving a reduction of the spring-elastic characteristics of the surround. In order to guarantee this, a value of a maximum of 0.05 mm should be selected for the film thickness of the film.

In a second aspect of the invention which is presented here, a thermoelectric device according to the invention has, instead of a spring-elastic structure forming a surround, a through-opening, provided in the housing wall, for the reducing of thermomechanical stresses. This is surrounded by a wall edge and is closed by a cover of a sheet metal film. According to the invention, the sheet metal film has a film thickness here which is at most one fifth, preferably at most one tenth of a wall thickness of the wall edge. Such a thinning of the housing wall gives the housing wall the desired spring-elastic characteristics in an analogous manner to the previously discussed spring-elastic structure.

A thermoelectric device according to the second aspect has a housing comprising a first and a second housing part and at least partially delimiting a housing interior. The two housing parts comprise respectively a housing wall, which lie opposite one another in a mounted state. In at least one of the two through-openings are provided for reduction of thermomechanical stresses in the housing, which is surrounded by a wall edge of the housing wall and closed by a cover of a sheet metal film.

Particularly good spring-elastic characteristics can be achieved, without endangering the structural integrity of the entire housing wall, when the sheet metal film has a film thickness of a maximum of 0.1 mm, and alternatively or additionally the housing wall has a wall thickness of at least 0.3 mm.

In an advantageous further development, the first housing part is constructed as a housing base, which is surrounded by a base collar, projecting inwards, towards the housing cover. Here, the base collar continues at an end facing away from the housing base into a flange section projecting outwards, away from the interior of the housing. The second housing part is constructed, by comparison, as a housing cover, which is fastened to the flange section of the housing base in a materially bonded manner, in particular by means of a welded connection. In variants, other forms of embodiment are also of course conceivable for the two housing parts. For instance, a construction of the two housing parts in the manner of a half shell respectively is to be considered.

In order to electrically insulate the electrically conductive housing with respect to the thermoelectrically active elements arranged in the interior of the housing, it is recommended in a preferred embodiment to provide an electrical insulation on at least one of the two housing walls—preferably on both —, which electrically insulates the thermoelectric elements with respect to the housing walls.

Preferably, the electrical insulation can be constructed as a multi-layered layer comprising an electrical insulation layer. Such an insulation layer can preferably be produced from a ceramic material, most preferably from aluminium oxide, or from a glass on silicon base. The insulation layer can be applied on the housing wall here for instance by means of a thermal spraying method or a plasma spraying method. Alternatively thereto, an application using a screen-printing or sintering method or a combination of these methods is also conceivable. Before the application of the insulation layer, it is recommended to degrease the housing wall and to activate it by means of sandblasting, etching or laser irradiation. Typically, the electrical insulation layer can be constructed so as to be single-layered or multi-layered and can have a layer thickness of several 100 micrometres. In order to prevent the occurrence of undesired electrical leakage currents through the insulation layer, this can be optionally interspersed with a plastic.

For the improved mechanical connection of the electrical insulation layer on the housing, it is proposed in an advantageous further development to provide an adhesive layer between the insulation layer and the housing wall, which adhesive layer acts as an adhesion promoter. This can be applied by means of the above-mentioned coating method, but also by means of PVD or CVD processes. Alternatively thereto, galvanic or electrochemical coating methods are also conceivable. Nickel, chrome, molybdenum, aluminium, yb, titanium, yttrium, boron, iron, carbon, nitrogen, oxygen, tungsten, tantalum or silver come into consideration as material for the adhesive layer. The actual electrical insulation layer can then be applied onto said adhesive layer.

In order to be able to arrange the conductor path elements, provided externally on the thermoelectrically active elements, for the electrical connecting of two adjacent elements on the electrical insulation layer, it is recommended to arrange a metal layer, for instance of copper, gold or silver, on a side of the electrical insulation layer facing away from the housing wall. This permits a simple arranging of the typically metallic conductor path elements of the thermoelectrically active elements. The arranging can take place by means of silver sintering or AMB soldering.

It is known that the different, previously discussed coatings and the housing material of the housing wall, but also the components of the thermoelectrically active materials typically have different coefficients of thermal expansion. For the reduction of thermomechanical stresses between the individual layers or respectively components, it is therefore proposed in a further preferred embodiment to provide one or more expansion coefficient adaptation layers between the electrical insulation layer and the adhesive layer. These adaptation layers are constructed here such that the coefficients of expansion of respectively adjacent layers only alter gradually. In an analogous manner, such an expansion coefficient adaptation layer can also be provided between the metal layer and the electrical insulation layer.

For the improved thermal coupling of the housing to an external temperature reservoir, it is proposed in a further preferred embodiment to provide a rib structure with at least two ribs, preferably with a plurality of ribs, on an outer side of the housing base facing away from the housing cover, which ribs project away from the housing base.

A particularly good thermal connection with said temperature reservoir is achieved by the ribs being configured structurally such that they form a wave-like structure in a profile viewed along the longitudinal direction of the housing, such that a rib arranged in the region of the aperture rests on the two edge sections of the housing base delimiting a respective aperture. In this way, it is prevented that the mechanically relatively rigidly constructed ribs reduce the bending flexibility of the housing base necessary for receiving thermomechanical stresses present in the housing base.

In order to be able to provide the electrical thermal tension generated by the thermoelectric elements externally on the housing, it is proposed to provide at least one through-opening, preferably two through-openings, in the housing collar. Through these, an electrical connection element can be passed respectively, which is connected at one end with a thermoelectric element or a conductor path element, and at the other end projects through the through-opening outwards out of the base collar.

In another preferred embodiment, the connection element is constructed as a metallic plug with a substantially cylindrical shape. In order to guarantee the necessary electrical insulation with respect to the housing, the connection element is arranged in an insulation sleeve of an electrically insulating material, in particular of a plastic.

In an advantageous further development of the thermoelectric generator, a (first or respectively second) through-opening can be provided respectively in each of the two opposite tube walls. A first heat exchanger device can then be inserted into the first through-opening, a second thermoelectric device into the second through-opening. The arrangement of the two devices in the two through-openings takes place here preferably such that the two housing bases of the two thermoelectric devices are facing each other.

The invention further relates to a motor vehicle with at least one previously presented thermoelectric device.

Further important features and advantages of the invention will emerge from the subclaims, from the drawings and from the associated figure description with the aid of the drawings.

It shall be understood that the features mentioned above and to be further explained below are able to be used not only in the respectively indicated combination, but also in other combinations or in isolation, without departing from the scope of the present invention.

Preferred example embodiments of the invention are illustrated in the drawings and are explained in further detail in the following description, wherein the same reference numbers refer to identical or similar or functionally identical components.

### BRIEF DESCRIPTION OF THE DRAWINGS

There are shown, respectively diagrammatically

FIG. 1 a first example of a thermoelectric device according to the invention, in a longitudinal section,

FIG. 2A the device of FIG. 1 in a perspective illustration,

FIG. 2B a detail illustration of the device of FIG. 2a in the region of the housing base,

FIG. 3 a second example of a thermoelectric device according to the invention, in a perspective illustration,

FIG. 4A a third example of a thermoelectric device according to the invention, in a perspective illustration,

FIG. 4B a detail illustration of the device of FIG. 4a in the region of the housing base,

FIG. 5A a web, forming the spring-elastic structure in the third example, in a longitudinal section,

FIG. 5B a first variant of the spring-elastic structure of FIG. 5a,

FIG. 5C a second variant of the spring-elastic structure of FIG. 5a,

FIG. 6 a variant of the thermoelectric device of FIG. 3,

FIG. 7A a detail illustration of the device of FIG. 6 in the region of a web,

FIG. 7B the device of FIG. 6 in a partial longitudinal section,

FIG. 8A a fourth example of the thermoelectric device according to the invention, in a longitudinal section,

FIG. 8B a detail illustration of FIG. 8a,

FIG. 8A a fourth example of the thermoelectric device according to the invention, in a longitudinal section,

FIG. 8B a detail illustration of FIG. 8a,

FIG. 9 a diagrammatic illustration, illustrating the layer construction of the electrical insulation,

FIG. 10 a perspective view of the housing base of the thermoelectric device with a rib structure arranged thereon,

FIG. 11 the housing base of FIG. 10 in a longitudinal section,

FIG. 12 a diagrammatic illustration of the housing base with thermoelectrically active elements arranged thereon, and electrical connection elements provided on the housing,

FIGS. 13A-C different variants of the electrical connection elemnet of FIG. 12, respectively in a longitudinal section.

### DETAILED DESCRIPTION

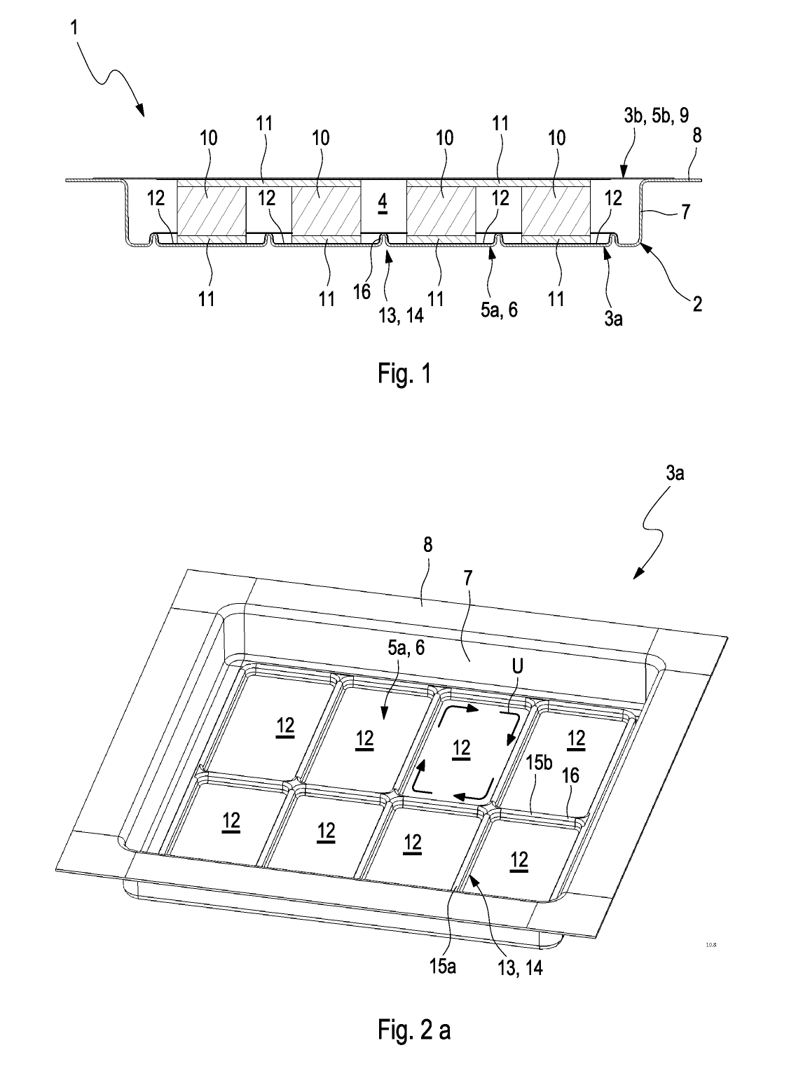

FIG. 1 illustrates in a longitudinal section a first example of a thermoelectric device 1 according to the invention. The thermoelectric device 1 comprises a housing 2 with a first and a second housing part 3a, 3b, which at least partially delimit a housing interior 4. The two housing parts 3a, 3b comprise respectively a housing wall 5a, 5b, which lie opposite one another in the mounted state shown in FIG. 1. As FIG. 1 shows, the first housing part 3a is constructed as housing base 6, which is surrounded by a base collar 7 projecting inwards towards the housing interior 4. Said base collar 7 continues at an end facing away from the housing base 6 into a flange section 8 projecting outwards, away from the housing interior 4. By comparison, the second housing part 3b is constructed as a housing cover 9, which is fastened to the flange section 8 of the housing base 6 in a materially bonded manner, by means of a welded connection. In the housing interior 4 several thermoelectric elements 10 are arranged, which are connected electrically with one another via metallic conductor path elements 11 and are therefore connected electrically in series. The mounting of the conductor path elements 11 on the thermoelectric elements 10 can take place by means of silver sintering or tin-based soldering.

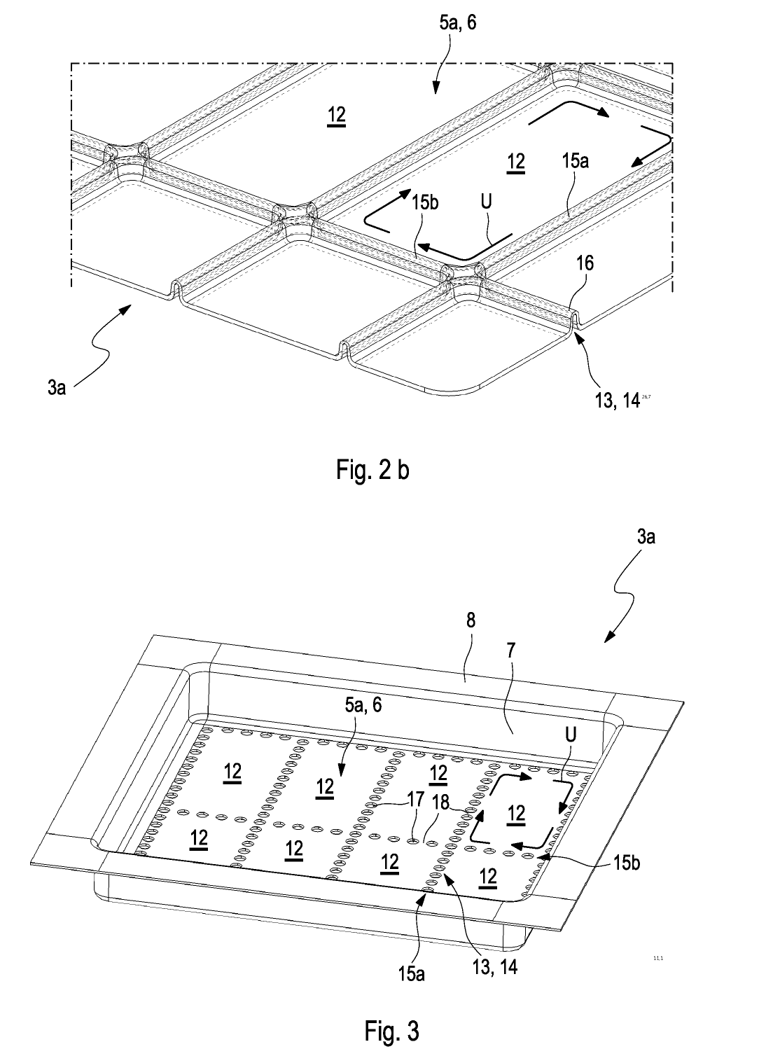

FIG. 2a shows the first housing part 3a in a perspective view, FIG. 2b in a detail illustration in the region of the housing wall 5a. On the housing wall 5a forming the housing base 6 eight receiving regions 12 are provided—in variants, of course, also a different number is conceivable —, which are enclosed respectively along a circulation direction U at least partially, even completely in the example of FIG. 2, by a surround 13. The surround 13 in turn has a spring-elastic structure 14, in order to provide the spring-elastic characteristics necessary for the compensation of thermomechanical stresses. The spring-elastic structure 14 is realized here as a bead 16 formed integrally on the housing wall 5a, which bead projects inwards from the first housing part 3a into the housing space 4. To increase its spring-elastic characteristics, the wall thickness of the housing wall 5a can be reduced in the region of the spring-elastic structure 14, in the example scenario of FIGS. 1 and 2 therefore in the region of the bead 16, with respect to the region of the housing wall 5a complementary to the spring-elastic structure 14. Furthermore, the bead 16 can have a u-shaped profile in transverse or respectively longitudinal section (cf. FIG. 1). The spring-elastic structure 14 is, in addition, constructed in a grid-like manner with respect to a top view onto the housing wall 5a and has several grid lines 15a and several grid gaps 15b, which cross each other at a right angle as shown in FIG. 2a.

It can also be seen from FIG. 2a that the receiving regions 12 have respectively substantially the geometry of a rectangle, in particular with rounded corners, with respect to a top view onto the housing wall 5a. The spring-elastic structure 14 is able, as already discussed, to receive and therefore compensate any thermomechanical stresses occurring in the housing 2, so that the receiving region 12, in which the thermoelectric elements 10 are arranged, remain free of such mechanical stresses. An undesired damage or even destruction of the structural integrity of the thermoelectrically active elements, which are sensitive with respect to mechanical stresses, can be largely or even completely prevented in this way.

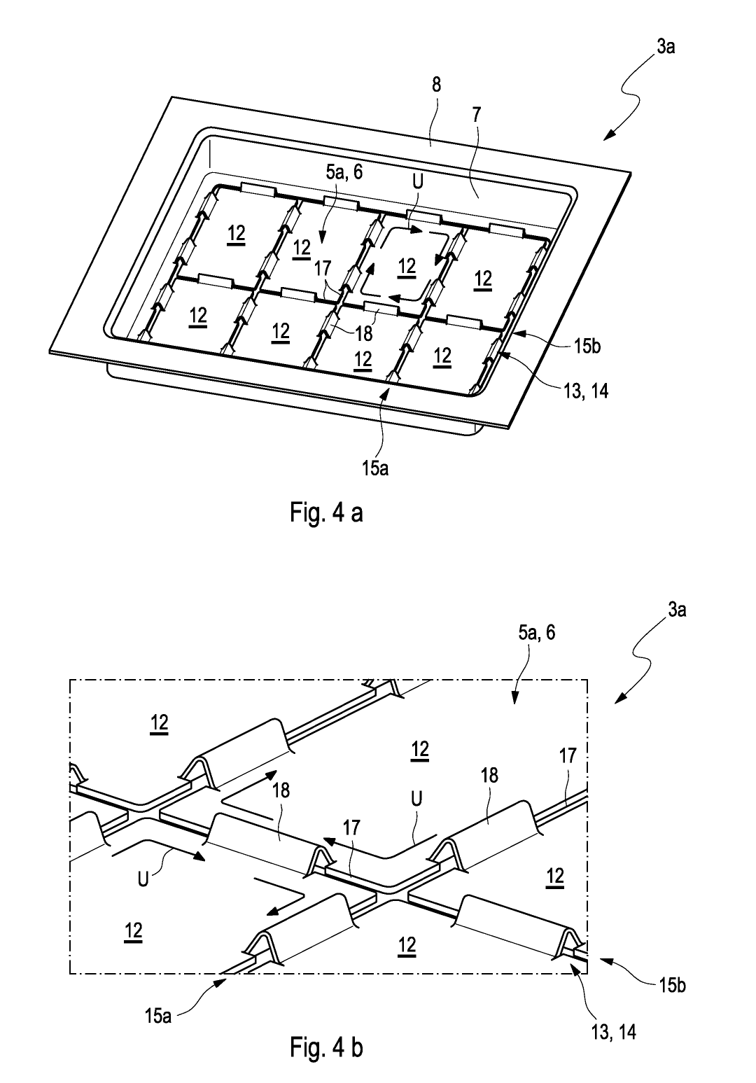

FIG. 3, meanwhile, shows a variant of the example of FIGS. 1 and 2, in which the spring-elastic structure 14 of the surround 13 is not constructed in the form of a beam, but rather has a plurality of apertures 17 provided along the circulation direction U, which are interrupted by webs 18 formed integrally on the housing wall 5a. As FIG. 3 shows, the surround 13 is configured from apertures 17 and webs 18 in the manner of a perforation. The apertures 17 can be constructed, for example, as circular through-openings, as shown in FIG. 4.

FIGS. 4a and 4b show a variant of the example of FIG. 3. FIG. 4a shows the first housing part 3a here in a perspective illustration, FIG. 4b shows a detail view of the first housing part 3a in the region of the housing base 6. In an analogous manner to the example of FIG. 3, the spring-elastic structure 14 of the surround 13 is formed by a plurality of apertures 17 provided along a circulation direction U, which are interrupted by webs 18 formed integrally on the housing wall 5a. In the example of FIG. 4, the apertures 17 are constructed in a slit-like manner along the circulation direction U, and the webs 18 project inwards into the housing interior 4 from a base plane formed by the housing base 6. In a further variant, it is conceivable to combine the slit-like apertures 17 of FIG. 4 with the webs 18 of FIG. 3 arranged in the base plane of the housing base 6.

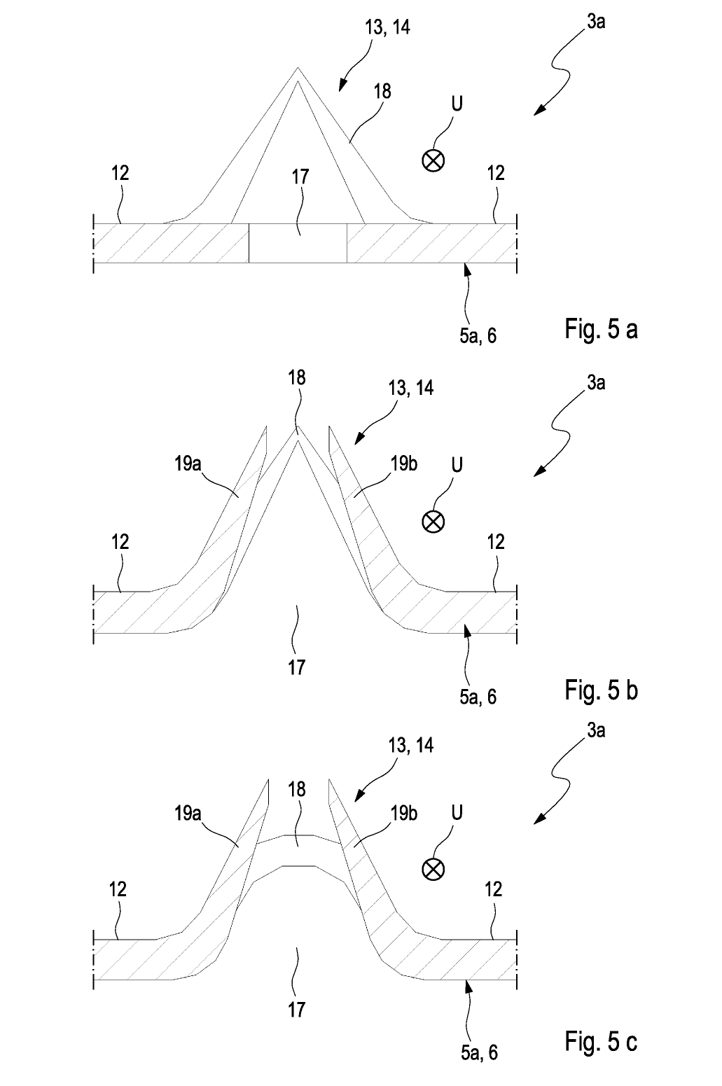

The webs 18 shown in FIGS. 4a and 4b can taper conically in a cross-section which is defined by a plane perpendicular to the circulation direction U. Such a scenario is illustrated by FIG. 5a, which shows a single web 18 in said cross-section. The webs 18 are formed integrally on the housing base 6. In particular, the web 18 can have a V-shaped profile, shown in FIG. 5a.

In a variant of the example of FIG. 5a, in turn, which is shown in FIG. 5b, the edge sections 19a, 19b of the housing base 6, delimiting the slit-like apertures 17 along the circulation direction U, can be bent up inwards towards the housing interior 4, i.e. project towards the housing interior 4.

FIG. 5c, finally, shows a variant of the example of FIG. 5a, in which the web 18 has a U-shaped profile in cross-section.

Generally, both the apertures 17 and also the webs 18 can be produced by means of a stamping process.

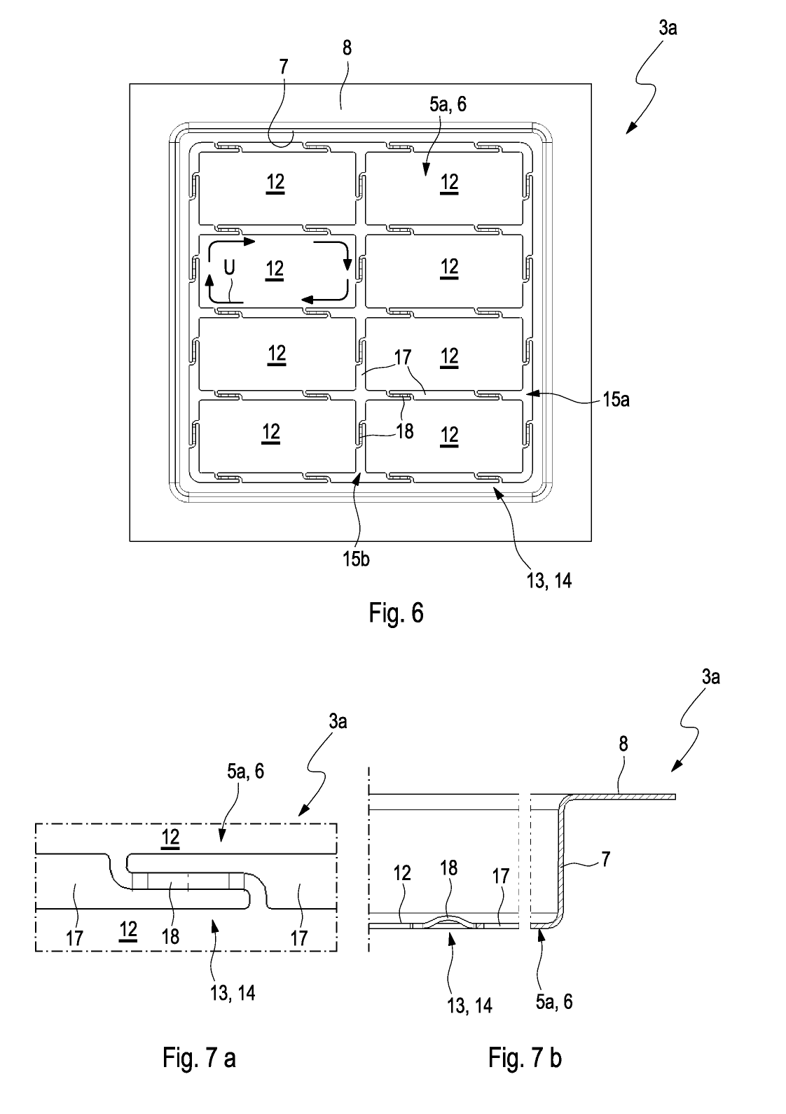

FIG. 6 shows a further variant of the thermoelectric device of FIG. 4, according to which the webs 18 have respectively a substantially S-like geometry with respect to the top view onto the housing base 6 shown in this figure. Each s-shaped web 18 is conditionally deformable in a spring-elastic manner for the receiving of thermomechanical stresses. This can be seen in particular from FIG. 7a, which illustrates a single such web 18 of FIG. 6 in a detail illustration. FIG. 7b shows the arrangement of FIG. 6 in a longitudinal section. It can be seen that the webs 18 can have a curved shape away from the housing base 6. This allows the webs 18 to compensate particularly high thermomechanical stresses.

As FIG. 6 shows in addition, each surround 13, surrounding a particular receiving region, has precisely six webs 18. In variants, this number can vary. FIG. 6 shows in addition that each surround 13 surrounding a particular receiving region has two longitudinal and two transverse sides, wherein in each longitudinal side precisely two webs 18 are provided, and in each transverse side precisely one web 18 is provided.

In all the examples explained above, on a side of the first housing part 3a facing away from the housing interior 4, a film of an electrically conductive material, in particular of a metal, or else of an electrically non-conductive material, can be applied, which covers the apertures 17 (not shown). Such a film can be, for example, a sheet metal film. By means of the film, the housing interior 4 of the housing 2 can be sealed with respect to the external environment of the housing 2, without this involving a reduction of the spring-elastic characteristics of the surround 13 or respectively of the spring-elastic structure 14. In order to guarantee this, the film thickness of the film should be a maximum of 0.05 mm and have a high thermal conductivity.

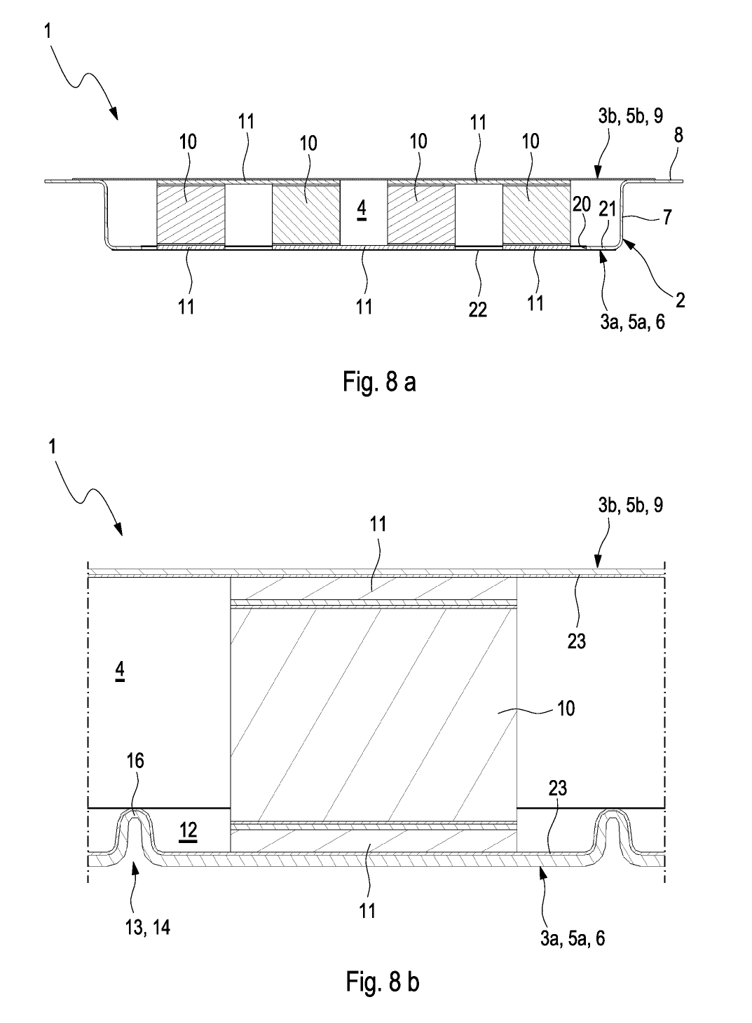

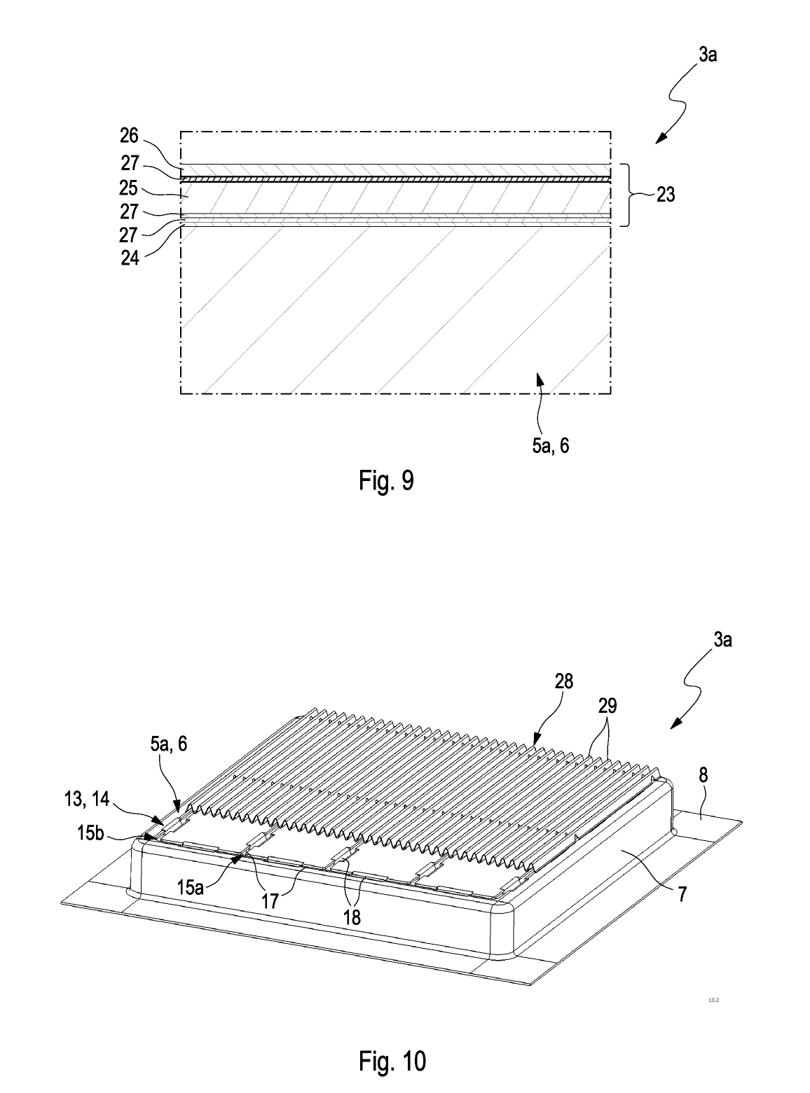

FIG. 8a shows in a longitudinal section a second example of a thermoelectric device 1 according to the invention. In an analogous manner to the example of FIG. 1, the device 1 comprises a housing 2 with a first and a second housing part 3a, 3b, which at least partially delimit a housing interior 4. The two housing parts 3a, 3b comprise respectively a housing wall 5a, 5b, which lie opposite one another in the mounted state shown in FIG. 8a. As FIG. 8a shows, the first housing part 3a is constructed as a housing base 6, which is surrounded by a base collar 7 projecting inwards towards the housing interior 4. Said base collar 7 continues at an end facing away from the housing base 6 into a flange section 8 projecting outwards away from the housing interior 4. By comparison, the second housing part 3b is constructed as a housing cover 9, which is fastened to the flange section 8 of the housing base 6 in a materially bonded manner, for example by means of a welded connection. In an analogous manner to the example of FIG. 1, several thermoelectric elements 10 are arranged in the housing interior 4, which elements are connected electrically with one another via conductor path elements 11. The housing wall 5a forming the housing base 6 has a through-opening 20, which is surrounded by a wall edge 21 of the housing base 6. The through-opening 20 is closed by a sheet metal film 22 which, on a side of the wall edge 21 facing away from the housing cover 9, is mounted thereon. The thermoelectric elements 10 are arranged on the sheet metal film 22. The sheet metal film 22 has a relative film thickness here which is at most one fifth, preferably at most one tenth, of a wall thickness of the wall edge 21 of the housing base 6. Typically, the absolute film thickness of the sheet metal film 22 is less than 0.1 mm and a wall thickness of the housing wall at least 0.3 mm. Such a thinning of the housing wall 5a by the use of a sheet metal film 22 gives the housing wall 5a the spring-elastic characteristics necessary for the receiving of thermomechanical stresses in an analogous manner to the already presented spring-elastic structure 14.

In order to electrically insulate the electrically conductive housing 2 with respect to the thermoelectrically active elements 10 arranged in the housing interior 4, there is provided on the two housing walls 51, 5b, lying opposite one another, of the two housing parts 3a, 3b respectively internally an electrical insulation 23, which can be constructed as a multi-layered layer. This is shown in FIG. 8b for the example according to FIG. 1, in which the spring-elastic structure 14 is constructed in the form of a bead 16. Of course, such an electrical insulation 23 can also be provided in all other previously discussed examples. The arranging of the conductor path elements 11 on the electrical insulation 23 can take place by means of silver sintering or AMB soldering.

In the example scenario according to FIG. 9, the electrical insulation 23 is constructed as a multi-layered layer and comprises an electrical insulation layer 25. The electrical insulation layer 25 can preferably be produced from a ceramic material, most preferably from aluminium oxide, or from a glass on silicon base. The insulation layer 25 can be applied on the housing wall 5a, 5b here for instance by means of a thermal spraying method or a plasma spraying method. Alternatively thereto, an application using a screen-printing or sintering method or a combination of these methods is also conceivable. Before the application of the insulation layer 25, it is recommended to degrease the housing wall and to activate it by means of sandblasting, etching or laser irradiation. Typically, the electrical insulation layer can be constructed so as to be single-layered or multi-layered and can have a layer thickness of several 100 micrometres. In order to prevent the occurrence of undesired electrical leakage currents through the insulation layer 25, this can be optionally interspersed with a plastic.

In FIG. 9 the layered structure of the electrical insulation layer 23 is explained in further detail. For the improved mechanical connection of the electrical insulation layer 25 on the housing 5a, an adhesive layer 24 is provided between the insulation layer 23 and the housing wall 5a, which adhesive layer acts as an adhesion promoter. This can be applied by means of the above-mentioned coating methods, but also by means of PVD or CVD processes. Alternatively thereto, galvanic or electrochemical coating methods are also conceivable. Nickel, chrome, molybdenum, aluminium, ytterbium, titanium, yttrium, boron, iron, carbon, nitrogen, oxygen, tungsten, tantalum or silver come into consideration as material for the adhesive layer 24. The actual electrical insulation layer 25 of the ceramic or the glass of silicon base can then be applied onto said adhesive layer 24.

In order to be able to apply the conductor path elements 11, provided externally on the thermoelectric elements 10, for the electrical connecting of two adjacent thermoelectric elements 10 on the electrical insulation layer 25, a metal layer 26 of copper, gold or silver is provided on a side of the insulation layer 25 facing away from the housing wall 5a. This facilitates the mounting of the metallic conductor path elements 11 of the thermoelectric elements 10. For the reduction of thermomechanical stresses between the individual layers or respectively components, two expansion coefficient adaptation layers 27 are provided between the insulation layer 25 and the adhesive layer 24. In an analogous manner, such an expansion coefficient adaptation layer 27, as shown in FIG. 9, can also be provided between the metal layer 26 and the electrical insulation layer 25.

FIG. 10 illustrates by way of example the integration of a rib structure 28 on an outer side of the housing base 6 facing away from the housing cover 9. FIG. 10 shows here the housing base 6 of the example of FIG. 4, but of course such a rib structure 28 can also be provided in the example embodiments shown by means of FIGS. 1 and 3. The rib structure 28 serves for the improved thermal coupling of the housing 2 to an external temperature reservoir, when the thermoelectric device 1 is to be used as a heat exchanger.

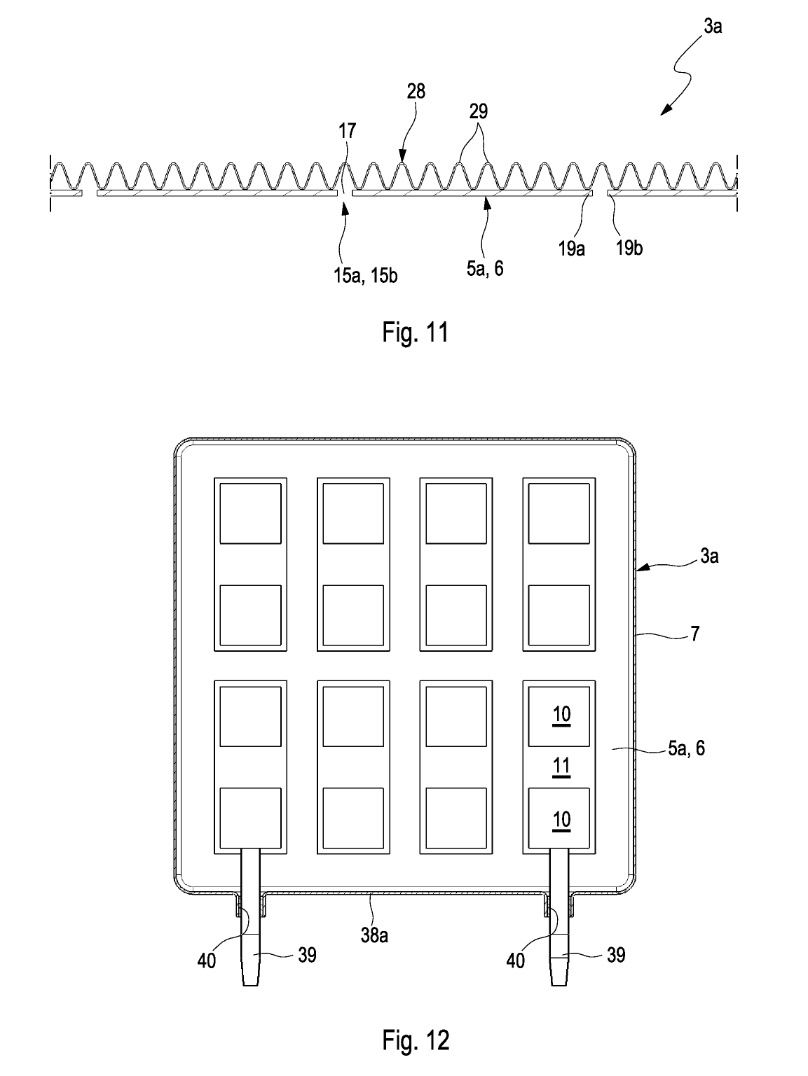

FIG. 11 shows the rib structure 28 with the ribs 29 and the arrangement thereof relative to the housing part 3a in a rough diagrammatic cross-section. The advantageous wave-shaped formation of the ribs 29 can be directly seen. As FIG. 11 additionally shows, the arrangement of the ribs 29 relative to the slit-like through-openings 17, forming a grid line 15a or respectively a grid gap 15b, takes place such that the distance of a respective rib 29 to the housing base 6 is maximum in the region of a grid line 15a or respectively grid gap 15b with the through-openings 17. In this way, it can be prevented that the ribs 29—typically constructed so as to be mechanically rigid—would reduce the spring-elasticity necessary for the receiving of thermomechanical stresses present in the housing base 6.

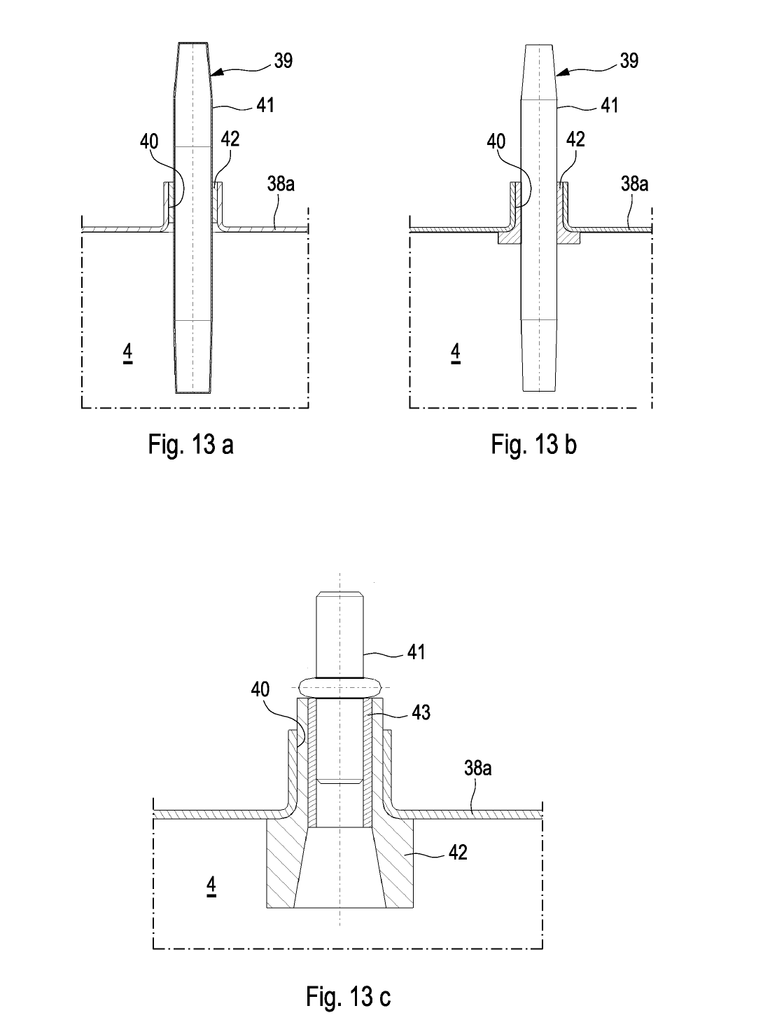

FIG. 12 shows, in a longitudinal section in a plane parallel to the one in which the housing base 6 is arranged, how the electrical and mechanical connection takes place of plug-like connection elements 39 to the thermoelectrically active elements 10. FIGS. 13a to 13c show, likewise in a longitudinal section, different structural forms of embodiment of the electrical connection elements 39 in a state inserted into the through-openings 40.

The connection elements 39 have a metallic plug body 41, for instance of a material containing copper, nickel, molybdenum, tungsten or iron. The plug bodies 41 can be embodied as round plugs or flat plugs and can be optionally equipped with a protective coating against oxidation or respectively corrosion. In addition, the electrical connection elements 39 can be provided with an electrical insulation 42, which electrically insulates the respective metallic plug body 41 with respect to the housing wall 38a. Typically, such an electrical insulation 42 is embodied as a sleeve-like component, which at least partially delimits the plug body 41 externally, as shown in FIGS. 13a to 13c. An elastomer, for example silicone, or a thermosetting plastic may come into consideration as material for the electrical insulation.

In the example of FIG. 13c, the connection element 39 has an electrically conductive connection sleeve 43 of a metal, which is inserted radially internally into the sleeve-like electrical insulation 42 and into which the plug body 41 can be inserted. The part of the plug body 41 projecting into the housing interior 4 can be electrically connected with a conductor path element 11 or directly with the thermoelectric elements 10.

1. A thermoelectric device, comprising:
a housing including a first housing part and a second housing part at least partially delimiting a housing interior, wherein the first housing part and the second housing part each include a housing wall, which are arranged opposite one another,
wherein at least one housing wall has at least two receiving regions, the at least two receiving regions respectively including at least one thermoelectric element arranged thereon, and
wherein each of the at least two receiving regions are surrounded by a surround extending along a circulation direction, the surround of the at least two receiving regions including a spring-elastic structure.

2. The thermoelectric device according to claim 1, wherein at least one of the receiving regions has a geometry of a rectangle with respect to an elevated view onto the at least one housing wall.

3. The thermoelectric device according to claim 1, wherein the spring-elastic structure defines a grid-like geometry with respect to an elevated view onto the at least one housing wall, wherein spring-elastic structure includes at least two grid lines and at least two grid gaps, wherein the at least two grid lines cross the at least two grid gaps.

4. The thermoelectric device according to claim 1, wherein the at least one housing wall has a wall thickness in a region spaced from the spring-elastic structure less than a wall thickness of the at least one housing wall in a region complementary to the spring-elastic structure.

5. The thermoelectric device according to claim 1, wherein the spring-elastic structure includes at least one bead disposed integrally on the at least one housing wall, wherein the at least one bead projects inwards into the housing interior from the at least one housing wall.

6. The thermoelectric device according to claim 1, wherein the spring-elastic structure includes at least two apertures extending along the circulation direction of the surround, wherein the at least two apertures are interrupted by at least one web disposed integrally on the at least one housing wall.

7. The thermoelectric device according to claim 6, wherein the at least one web connects the at least two receiving regions by bridging the at least two respective apertures transversely to the circulation direction.

8. The thermoelectric device according to claim 7, wherein the at least one web includes a substantially S-shaped geometry with respect to an elevated view onto a housing base of the housing.

9. The thermoelectric device according to claim 7, wherein at least one of the surrounds surrounding one of the at least two receiving regions has precisely six webs.

10. The thermoelectric device according to claim 7, wherein the surround surrounding the at least two receiving region each include two longitudinal sides and two transverse sides, wherein the two longitudinal sides respective have two webs and the two transverse sides have one web.

11. The thermoelectric device according to claim 7, wherein the at least one web is profiled to include an inwards curved, in a direction towards the housing interior and away from a housing base of the housing.

12. The thermoelectric device according to claim 7, wherein the at least one web tapers in cross-section away from the at least one housing wall into the housing interior.

13. The thermoelectric device according to claim 7, wherein:
the at least two apertures and at least two webs alternate along the circulation direction, and
the at least two webs define at least two grid lines and the at least two apertures define at least two grid gaps, wherein at least one of the grid lines and at least one of the grid gaps cross each other.

14. The thermoelectric device according to claim 7, wherein at least one of:
at least one of the at least one webs and the at least two apertures are arranged in a wall plane defined by the at least one housing wall, and
the at least one web projects at least partially inwards into the housing interior from a wall plane defined by the housing wall.

15. The thermoelectric device according to claim 7, wherein the at least one housing wall includes an edge section extending along the circulation direction and at least partially delimiting the at least two apertures, wherein the edge section projects inwards into the housing space.

16. The thermoelectric device according to claim 5, wherein the at least one bead has a substantially U-shaped profile with respect to a cross-section of the at least one housing wall.

17. The thermoelectric device according to claim 7, wherein the at least two apertures and the at least one webs are formed via a stamping process.

18. The thermoelectric device according to claim 1, wherein the housing wall on a side facing away from the housing interior includes a film of at least one of an electrically conductive material and a non-conductive material mounted thereon, which covers the at least two apertures.

19. The thermoelectric device according to claim 18, wherein the film has a film thickness of a maximum of 0.05 mm.

20. A thermoelectric device, comprising:
a housing including a first housing part and a second housing part at least partially delimiting a housing interior, wherein the first housing part and the second housing part respectively include a first housing wall and a second housing wall, which are arranged opposite one another,
wherein at least one the first housing wall and the second housing wall includes a through-opening for reducing a thermomechanical stress in the housing, wherein the through-opening is surrounded by a wall edge and a covered by a sheet metal film, wherein the sheet metal film has a film thickness which is at most one fifth of a wall thickness of the wall edge.

21. The thermoelectric device according to claim 20, wherein at least one of the film thickness of the sheet metal film is a maximum of 0.1 mm, and the wall thickness of the housing wall is at least 0.3 mm.

22. The thermoelectric device according to claim 20, wherein:
the first housing part defines a housing base, the housing base being surrounded by a base collar projecting inwards towards the second housing part,
the base collar extends at an end facing away from the housing base into a flange section projecting outwards away from the housing interior, and
the second housing part defines a housing cover, which is fastened to the flange section of the housing base via a materially bonded connection.

23. The thermoelectric device according to claim 20, wherein at least one of the first housing wall and the second housing wall includes an electrical insulation, which electrically insulates a thermoelectric element disposed in the housing interior with respect to the at least one of the first housing wall and the second housing wall.

24. The thermoelectric device according to claim 23, wherein the electrical insulation includes an electrical insulation layer composed of a ceramic material.

25. The thermoelectric device according to claim 24, wherein at least one of:
the electrical insulation layer includes a metal layer on a side facing away from the at least one of the first housing wall and the second housing wall, and
an adhesive layer is arranged between the electrical insulation layer and the at least one of the first housing wall and the second housing wall.

26. The thermoelectric device according to claim 25, further comprising at least one of:
a first expansion coefficient adaptation layer arranged between the electrical insulation layer and the adhesive layer, and
a second expansion coefficient adaptation layer arranged between the metal layer and the electrical insulation layer.

27. The thermoelectric device according to claim 22, wherein the housing base includes a rib structure with at least two ribs projecting from an outer side of the housing base facing away from the housing cover.

28. The thermoelectric device according to claim 27, wherein the at least two ribs are profiled to define a wave-like structure along a longitudinal direction of the housing, wherein the at least two ribs rests on at least two edge sections of the housing base which delimit an aperture.

29. The thermoelectric device according to claim 20, wherein the housing includes an opening receiving an electrical connection element, the electrical connection element connected electrically at one end with at least one of a thermoelectric element and a conductor path element, and at the other end the electrical connection element projects outwards from the housing through the opening.

30. The thermoelectric device according to claim 29, wherein
the electrical connection element includes a metallic plug body and an electrical insulation composed of an electrically insulating material for electrically insulating the plug body with respect to the housing.

31. (canceled)
